(19) United States
(12) Patent Application Publication
(10) Pub. No.: US 2026/0169316 A1
(43) Pub. Date: Jun. 18, 2026

(54) WAVEGUIDE PHOTODIODE AND MONOLITHIC ELECTRO-PHOTONIC INTEGRATED CIRCUIT COMPRISING A WAVEGUIDE PHOTODIODE AND TRANSIMPEDANCE AMPLIFIER

(71) Applicant: ElectroPhotonic-IC Inc., Kanata (CA)

(72) Inventors: Lawrence E. TAROF, Kanata (CA); Vighen PACRADOUNI, Montreal (CA); Kirill PIMENOV, Orleans (CA); Yury LOGVIN, Kanata (CA); Dhiraj KUMAR, Redondo Beach, CA (US); Eric CAUCHON, Ottawa (CA); Richard D. CLAYTON, Ottawa (CA); Francois TREMBLAY, Gatineau (CA); Ken TOWNSEND, Calgary (CA)

(21) Appl. No.: 19/296,121

(22) Filed: Aug. 11, 2025

Related U.S. Application Data
(60) Provisional application No. 63/734,954, filed on Dec. 17, 2024.
(60) Provisional application No. 63/736,173, filed on Dec. 19, 2024.

(51) Int. Cl. G02F 1/015; G02F 1/025; H10F 30/223; H10F 77/124

(52) U.S. Cl. CPC G02F 1/0157; G02F 1/025; H10F 30/223; H10F 77/1248

(57) ABSTRACT

A waveguide (WG)-device comprising a p type material, an i-type material and an n-type materials (a PIN waveguide), the waveguide device comprising: a semi-insulating (SI) indium phosphide (InP) substrate; an epitaxial layer stack formed on the SI:InP substrate structured to form the PIN waveguide, the epitaxial layer stack comprising: an n-layer structure and a p-layer structure; an i-region comprising optical material having an operational wavelength range located between the n-layer structure and the p-layer structure; the n-layer structure and the p-layer structure providing a mode-shaping functionality configured to optical confine one or more modes of an optical signal configured to propagate through the i-region; wherein the mode-shaping functionality includes providing a mode-extending functionality in at least one of the n-layer structure and the p-layer structure.

### CROSS-REFERENCE TO RELATED APPLICATIONS

This application claims the benefit of U.S. provisional patent application No. 63/736,173 entitled “Waveguide Photodiode And Monolithic Electro-Photonic Integrated Circuit Comprising A Waveguide Photodiode And Transimpedance Amplifier” filed Dec. 19, 2024, and 63/734,954 entitled “Electro-Absorption Modulator And Monolithic Electro-Photonic Integrated Circuit Comprising An Electro-Absorption Modulator And Driver” filed Dec. 17, 2024 incorporated herein by reference in their entirety.

This application is related to U.S. patent application Ser. No. 18/973,578 filed Dec. 9, 2024, entitled “Optical Receiver comprising Monolithically Integrated Photodiode and Transimpedance Amplifier”, which is a continuation of U.S. patent application Ser. No. 17/785,989, filed Jun. 16, 2022, entitled “Optical Receiver comprising Monolithically Integrated Photodiode and Transimpedance Amplifier”, which is a Continuation-in-Part of PCT International patent application no. PCT/CA2020/051666, filed Dec. 4, 2020, claiming priority from U.S. provisional patent application No. 62/950,479, filed Dec. 19, 2019; 63/734,954 entitled “Electro-Absorption Modulator And Monolithic Electro-Photonic Integrated Circuit Comprising An Electro-Absorption Modulator And Driver” filed Dec. 17, 2024. All these applications are incorporated herein by reference in their entirety.

### TECHNICAL FIELD

This invention relates to waveguide photodiodes and electro-photonic integrated circuits comprising waveguide photodiodes, fabricated with III-V semiconductor materials, such as an Indium Phosphide (InP)-based materials system.

### BACKGROUND

The above referenced patent applications disclose monolithic integration of a photodiode (PD) with a transimpedance amplifier (TIA) using III-V semiconductor materials, such as an Indium Phosphide (InP)-based materials system. The photodiode may be a surface-receiving PIN-PD having a top facet optical window, or an edge-receiving waveguide PD having a lateral facet window.

Surface-receiving PIN-PDs may be referred to as vertical PINs or Normal Incidence PINs. They offer ease of coupling from an optical fiber to a circular top facet window, if necessary, using a lens. Responsivity can be increased by increasing the thickness of the i-region but increasing the thickness of the i-region increases the carrier transit time. To achieve both increased bandwidth and increased responsivity (QE) together, a mirror or reflector can be added to allow for two-passes of absorbed light, i.e. to increase the effective thickness of the i-region. However, surface receiving PDs cannot meet the performance requirements for the next generation of optical data communications. For example, surface entry, integrated lens PDs can just about reach the Nyquist limit for 112 GB/224 Gb/s, but with poor quantum efficiency. It is impractical to extend surface entry PDs to 224 Gb/s-448 Gb/s.

For waveguide PDs, having a rectangular waveguide with a lateral facet window, wherein the i-region is of length l, width w and thickness d, the responsivity is dependent on the length of the waveguide and independent of the carrier transit time, which is dependent on d. However, the window dimension depends on the cross-section of the waveguide, i.e. w*d, and the spot size of the input light must be edge-coupled to a relatively small optical window, which presents a challenge for efficient optical coupling.

There is a need for waveguide PDs and monolithic electro-photonic integrated circuits comprising waveguide PDs, which address one or more of these challenges, or otherwise provide improved performance, for applications such as high-speed optical data communications.

### SUMMARY OF INVENTION

The present invention seeks to provide improved or alternative waveguide photodiodes for applications such as high-speed optical data communications.

According to an aspect of the present invention there is provided a waveguide (WG)-device comprising a p type material, an i-type material and an n-type materials (a PIN waveguide), the waveguide device comprising: a semi-insulating (SI) indium phosphide (InP) substrate; an epitaxial layer stack formed on the SI:InP substrate structured to form the PIN waveguide, the epitaxial layer stack comprising: an n-layer structure and a p-layer structure; an i-region comprising optical material having an operational wavelength range located between the n-layer structure and the p-layer structure; the n-layer structure and the p-layer structure providing a mode-shaping functionality configured to optical confine one or more modes of an optical signal configured to propagate through the i-region; wherein the mode-shaping functionality includes providing a mode-extending functionality in at least one of the n-layer structure and the p-layer structure.

In an aspect, the waveguide device is a waveguide-photodiode, and the i-region is an absorptive optical material.

In an aspect, the mode-extending functionality is provided by configuring a refractive index of the material of the i-region to be higher than a refractive index of the n-layer structure and a refractive index of the p-layer structure.

In an aspect, the n-layer structure includes at least one of an n-cladding layer and an-contact layer and the p-layer structure includes at least one of a p-cladding layer and p-contact layer.

In an aspect, the mode-extending functionality comprises a mode-extending layer.

In an aspect, the mode-extending layer comprises a quaternary material such as materials fabricated with group III-V semiconductor materials, including an Indium Phosphide (InP)-based material system comprising and other compositions of In, Ga, As, P, Al and Sb.

In an aspect, the mode-extending layer comprises an n-type layer in the n-layer structure.

In an aspect, the mode-extending layer comprises a p-type layer in the p-layer structure.

In an aspect, the mode-extending layer comprises a p-type layer in the p-layer structure and an n-type layer in the n-layer structure.

In an aspect, the mode-extending functionality is provided by balancing one or more parameters of the waveguide device.

In an aspect, one or more parameters of the waveguide device comprise two or more of: parameters of a compositions, size, materials or doping of the epitaxial layer stack; inclusion of one or more mode-shaping structures; inclusion of one or more mode-extending layer; inclusion of one or more separate confinement heterostructure (SCH) layers; defining a refractive index of each layer of the epitaxial layer stack; selecting processing from MBE. MOCVD, or any other process; balancing fall-off of voltage and/or electric field profile over a length of the i-region; balancing a width of the i-region relative to the width of the waveguide device; a transit time of the carriers (holes or electrons as the case may be); a difference between the transit times of holes and electrons; balancing a thickness d of the i-region and the transit time, grading of one or more layers of the epitaxial layer stack; inclusion of multi-quantum well MQW material and where used balancing a number of wells and barriers and a ratio of wells to barriers; providing an undercut to the i-region for reducing the width of the i-region relative to the width of the ridge of the waveguide, e.g. to reduce capacitance; balancing an absorption length of the i-region with a RC value thereof; balancing one or more parameter to accommodate absorption of a single mode or multiple modes in the i-region; balancing a waveguide width, waveguide length and thickness of the i-region to provide a quantum efficiency (QE) of between ≥80% and (QE) ≥90% over a required operational wavelength range; balancing a waveguide width, waveguide length and thickness of the i-region to provide a capacitance of ≤0.70 fF/μm of length; and wherein the waveguide is a ridge waveguide having a ridge width and a ridge length, and the i-region has a waveguide width which is less that the ridge width.

In an aspect, the material of the i-region comprises InGaAs.

In an aspect, the material of the i-region comprises a quaternary absorption material selected within the InGaAlAsP quintenary system, lattice matched to InP.

In an aspect, the material of the i-region comprises a Quantum Confined Stark Effect (QCSE) multi-quantum well (MQW) structure, comprising N wells and N−1 barriers.

In an aspect, N is between ≥8 and <24.

In an aspect, the well thickness, the barrier thickness and N are selected to provide a thickness d of the i-region which is close to a transit time limit of the i-region.

In an aspect, a ratio of the barrier thickness to well thickness is 1:1 to <1:1 and preferably 6:10, and the barrier thickness and the well thickness are in a range of 9 nm to 11 nm. In an aspect, a width of the i-region is tapered, having a first width at an optical input and narrowing to a second width at a back facet of the waveguide device.

According to an aspect of the present invention there is provided an optical device comprising a waveguide device according to another aspect and further comprising a monolithically integrated first plurality of layers of the epitaxial layer stack forming at least one electronic device.

In an aspect, the waveguide device is a waveguide-photodiode or an electro-absorption modulator (EAM).

In an aspect, the at least one electronic device comprises a transimpedance amplifier (TIA) or an electro-absorption modulator (EAM) driver.

In an aspect, the optical device is a receiver, the waveguide device is a waveguide-photodiode and the at least one electronic device comprises a transimpedance amplifier (TIA).

In an aspect, the optical device is a transmitter, the waveguide device is an electro-absorption modulator (EAM) and the at least one electronic device comprises an electro-absorption modulator (EAM) driver.

In an aspect, the TIA comprises InP heterojunction bipolar transistors (HBTs) formed by a first plurality of layers of the epitaxial layer stack formed on the SI InP substrate and the waveguide device is formed by a second plurality of semiconductor layers overlying the first plurality of semiconductor layer.

In an aspect, device parameters comprise a capacitance of the waveguide-photodiode, and a capacitance CTIA of the TIA, wherein: device parameters comprising said CTIA and CPD, dimensions of the i-region of the waveguide-photodiode comprising an area of the waveguide-photodiode and a thickness of the i-region, and a transimpedance feedback resistance RF of the TIA are selected to provide an integrated waveguide-photodiode-TIA meeting device specifications comprising a specified sensitivity and responsivity for a required operational wavelength range.

In an aspect, the waveguide-photodiode and the transimpedance amplifier (TIA) are formed monolithically on semi-insulating (SI) indium phosphide (InP).

According to an aspect of the present invention there is provided an optical system comprising an optical device according to another aspect.

In an aspect, comprising two or more optical devices.

In an aspect, an optical device operating as a transmitter and one or more optical devices acting as a receiver.

According to an aspect of the present invention there is provided a method of manufacturing a waveguide device comprising a p type material, an i-type material and an n-type materials (a PIN waveguide) of claim 1, comprising: forming an epitaxial layer stack on a semi-insulating (SI) indium phosphide (InP) substrate and structured to form the PIN waveguide, the method comprising: forming an n-layer structure and a p-layer structure; and forming an i-region comprising optical material having an operational wavelength range located between the n-layer structure and the p-layer structure; wherein the n-layer structure and the p-layer structure provide a mode-shaping functionality configured to optical confine one or more modes of an optical signal configured to propagate through the i-region; and wherein the mode-shaping functionality includes providing a mode-extending functionality in at least one of the n-layer structure and the p-layer structure.

Aspects of the invention provide a waveguide photodiode and a monolithic electro-photonic integrated circuit comprising a waveguide photodiode and a transimpedance amplifier, which may be fabricated with e.g. group III-V semiconductor materials, such as an Indium Phosphide (InP)-based material system comprising binary, ternary, quaternary and other compositions of In, Ga, As, P, Al and Sb.

One aspect provides waveguide photodiode (PD) comprising: a semi-insulating (SI) indium phosphide (InP) substrate; an epitaxial layer stack formed on the SI:InP substrate structured to form a ridge waveguide of the WG-PD, the epitaxial layer stack comprising: an n-contact layer; an n-cladding; an i-region comprising optical absorption material for an operational wavelength range; a p-cladding; a p-contact layer; an n-metal contact on the n-contact layer, and a p-metal contact layer on the p-contact layer; wherein the p-cladding comprises a first mode-shaping section comprising a p-InP spacer layer and the n-cladding comprises a second mode-shaping section comprising an n-InP spacer layer; at least one of the first mode-shaping section and the second mode-shaping section comprises a mode-extending layer, the mode-extending layer having a refractive index less than the refractive index of the absorption material of the i-region and greater than the refractive index of said InP spacer layers. a thickness d of the i-region is related to a carrier transit time limit of the i-region.

For example, one embodiment provides a waveguide photodiode comprising: a semi-insulating (SI) indium phosphide (InP) substrate; an epitaxial layer stack formed on the SI:InP substrate structured to form a ridge waveguide of the photodiode, the epitaxial layer stack comprising: an n-contact layer comprising n-InGaAs; a first mode-shaping-section comprising an n-InP spacer layer a first separate confinement heterostructure; an i-region comprising absorption material; a second separate confinement heterostructure; a second mode-shaping section comprising: a mode-extending layer comprising a p-type material having a refractive index greater than the refractive index of InP and less than the refractive index of the i-region and a p-InP spacer layer on the mode-extending layer; an overlying p-contact layer; and an n-metal contact on the n-contact layer, and a p-metal contact layer on the p-contact layer.

Another embodiment provides provides a waveguide photodiode comprising: a semi-insulating (SI) indium phosphide (InP) substrate; an epitaxial layer stack formed on the SI:InP substrate structured to form a ridge waveguide of the photodiode, the epitaxial layer stack comprising: an p-contact layer comprising p-InGaAs; a first mode-shaping-section comprising an p-InP spacer layer a first separate confinement heterostructure; an i-region comprising absorption material; a second separate confinement heterostructure; a second mode-shaping section comprising: a mode-extending layer comprising a n-type material optionally having a refractive index greater than the refractive index of InP and less than the refractive index of the i-region and a n-InP spacer layer on the mode-extending layer; an overlying n-contact layer; and an n-metal contact on the n-contact layer, and a p-metal contact layer on the p-contact layer.

In some embodiments, the absorption material of the i-region comprises InGaAs, or a quaternary absorption material selected from within the InGaAlAsP quintenary system, lattice matched to InP.

In some embodiments the absorption material of the i-region comprises a Quantum Confined Stark Effect (QCSE) multi-quantum well (MQW) structure comprising N wells and N−1 barriers, for example N is ≥8 or N is ≥13; a ratio of a barrier thickness to a well thickness is 1:1; or a ratio of a barrier thickness to a well thickness is <1:1. In an example embodiment ratio of a barrier thickness to a well thickness is 6:10, e.g. a barrier thickness of 6 nm and a well thickness of 10 nm.

The ridge of the waveguide has a width and a length, and the i-region may have a waveguide width which is less than the width of the ridge. The width of the i-region may be tapered, having a first width at an optical input and narrowing to a second width at a back facet of the waveguide PD. The back facet of the waveguide PD may comprise a mirror.

For example, the waveguide materials and dimensions are selected to provide: a capacitance of ≤0.70 fF/μm of length; and a quantum efficiency of ≥80%, or ≥90%, for the required operational wavelength range.

Another aspect provides a monolithic electro-photonic integrated circuit comprising the waveguide PD as defined herein and an electronic circuit comprising a transimpedance amplifier (TIA). For example, the monolithic electro-photonic integrated circuit comprises: an epitaxial layer structure is formed on a semi-insulating (SI) indium phosphide (InP); the electronic circuit comprising the TIA comprises InP heterojunction bipolar transistors (HBTs) formed by a first plurality of layers of the epitaxial layer stack formed on the SI InP substrate; and the waveguide PD is formed by a second plurality of semiconductor layers overlying the first plurality of semiconductor layers, the first and second plurality of semiconductor layers being separated a spacer layer; and a contact of the waveguide PD is directly interconnected by a conductive trace to an input of the TIA. In another aspect, there is provided an optical receiver comprising a monolithically integrated waveguide photodiode (PD) and transimpedance amplifier (TIA), wherein: an epitaxial layer structure is formed on a semi-insulating (SI) indium phosphide (InP); the TIA comprises InP heterojunction bipolar transistors (HBTs) formed by a first plurality of layers of the epitaxial layer stack formed on the SI InP substrate; and the waveguide PD is as defined herein, formed by a second plurality of semiconductor layers overlying the first plurality of semiconductor layers; and a contact of the PD is directly interconnected by a conductive trace to an input of the TIA.

For example, the epitaxial layer stack comprising a spacer, e.g. a semi-insulating layer, comprising one or more intermediate layers between the first plurality of semiconductor layers and the second plurality of semiconductor layers. For example, the TIA is formed on a first area of the substrate, and the waveguide PD is provided on an adjacent area, and comprising an isolation region electrically isolating the first plurality of semiconductor layers of the first area from the first plurality of semiconductor layers of the adjacent area.

Device parameters comprise a capacitance C_{PD} of the PD, and a capacitance C_{TIA} of the TIA, wherein: device parameters comprising said C_{TIA} and C_{PD}, dimensions of the i-region of the PD comprising an area of the PD and a thickness of the i-region, and a transimpedance feedback resistance R_{F} of the TIA are selected to provide an integrated waveguide PD-TIA meeting device specifications comprising a specified sensitivity and responsivity for a required operational wavelength range. In some embodiments, values of C_{PIN} and C_{TIA} provide at least one of: a) C_{PIN} is matched to C_{TIA}; b) C_{PIN} is approximately equal to C_{TIA}; and c) a minimum combined capacitance (C_{PIN}+C_{TIA}).

Thus waveguide photodiodes, monolithic electro-photonic integrated circuits comprising a waveguide photodiode and electronic circuit comprising TIA, and an optical receiver comprising a monolithically integrated waveguide photodiode and TIA of example embodiments are described, wherein the absorption material and the waveguide geometry and dimensions comprising a waveguide width, waveguide length and thickness of the i-region are selected to provide a capacitance of ≤0.70 fF/μm of length, and e.g. a quantum efficiency (QE) ≥80% or ≥90% over a required operational wavelength range.

### BRIEF DESCRIPTION OF THE DRAWINGS

FIG. 1 is a schematic diagram to illustrate ease of use of various types of photodiodes as a function of evolution of optical data communications as indicated by bit rate per lane on a log scale;

FIG. 2 is a simplified schematic diagram of a surface-receiving vertical PIN PD with a top facet window, and normal incidence, in an aspect of the invention;

FIG. 3 explains how the device parameters are related for a vertical PIN PD, in an aspect of the invention;

FIG. 4 shows a simplified schematic diagram of an edge-receiving waveguide PD with a lateral facet window, in an aspect of the invention;

FIG. 5 explains how the device parameters are related for a waveguide PD, in an aspect of the invention;

FIG. 6a and FIG. 6b are simplified schematic cross-sectional views of a waveguide device such as a PD of an embodiment comprising a mode-extending layer and optional upper and lower mode-shaping sections in an aspect of the invention;

FIG. 7 is a simplified schematic cross-sectional view of a waveguide device such as a PD of an embodiment wherein the i-region comprises InGaAs in an aspect of the invention;

FIG. 8 is a simplified schematic cross-sectional view of a waveguide PD of an embodiment wherein the i-region comprises a quaternary absorption material within the InGaAlAsP quintenary materials system, which is lattice matched to InP in an aspect of the invention;

FIG. 9 is a simplified schematic cross-sectional view of a waveguide PD of an embodiment wherein the absorption material of the i-region comprises a QCSE MQW structure of N wells (W) and (N−1) barrier layers (B), which is denoted by “N×W+(N−1)×B”, in an aspect of the invention;

FIG. 10 is a simplified schematic cross-sectional view of a waveguide device such as a PD of an embodiment wherein the p region is up and the mode-extending layer is above i-region, in an aspect of the invention;

FIG. 11 is a simplified schematic cross-sectional view of a waveguide device such as a PD of an embodiment wherein the n-region is up and the mode-extending layer is above i-region, in an aspect of the invention;

FIG. 12 is a simplified schematic cross-sectional view of a waveguide device such as a PD of an embodiment wherein the p-region is up and the mode-extending layer is below i-region, in an aspect of the invention;

FIG. 13 is a simplified schematic cross-sectional view of a waveguide device such as a PD of an embodiment wherein the p-region is up and the mode-extending layer is both above and below i-region, in an aspect of the invention;

FIG. 14 shows some comparative data for two surface illuminated PD and a waveguide PD, in an aspect of the invention;

FIG. 15 is a simplified cross-sectional view of an epitaxial layer structure for fabrication of a monolithic electro-photonic circuit comprising a waveguide device such as a PD and an electronic circuit comprising a transimpedance amplifier, in an aspect of the invention;

FIG. 16 shows a simplified view of an epitaxial layer structure for fabrication of a monolithic electro-photonic circuit comprising a waveguide device such as a PD and electronics comprising a transimpedance amplifier, in an aspect of the invention;

FIG. 17 shows a simplified cross-sectional view of a monolithic electro-photonic integrated circuit comprising a waveguide device such as a PD and electronics such as a transimpedance amplifier (TIA), in an aspect of the invention;

FIG. 18 shows a simplified equivalent circuit schematic for the PD and TIA to illustrate key parameters for design of the monolithically integrated PD-TIA design of the example embodiment, in an aspect of the invention; and

FIG. 19 shows an example circuit layout for a monolithically integrated waveguide PD and TIA, in an aspect of the invention.

The foregoing and other features, aspects and advantages will be more apparent from the following detailed description, taken in conjunction with the accompanying drawings, of example embodiments, which description is by way of example only.

### DETAILED DESCRIPTION

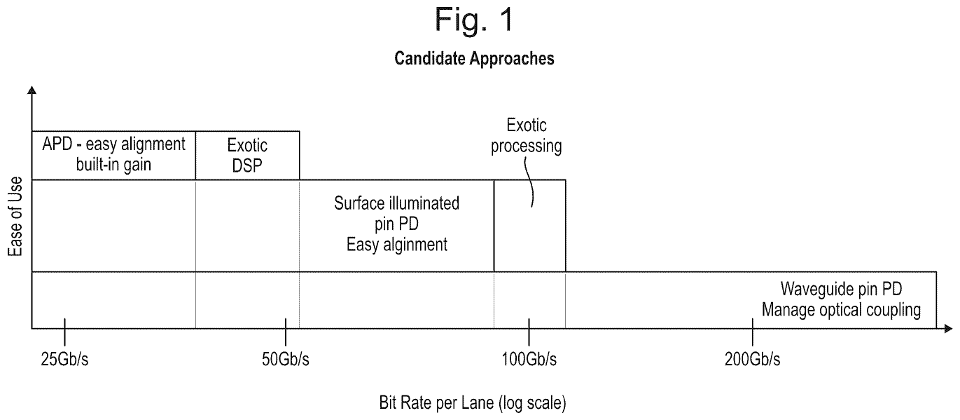

FIG. 1 is a schematic diagram to illustrate ease of use of various types of photodiodes as a function evolution of optical data communications as indicated by it rate per lane on a log scale. Avalanche photodiodes have built in gain and offer ease of alignment. With exotic digital signal processing they can handle bit rates just over 50 Gb/s. Surface illuminated, vertical, pin-PDs offer ease of alignment and with processing enhancements can handle bit rates over 100 Gb/s. Waveguide PDs can provide improved performance for 112 GB/224 Gb/s, and beyond, if the issues for optical coupling and manufacture are resolved. For example, the issue of efficient optical coupling to a lateral facet window can be managed.

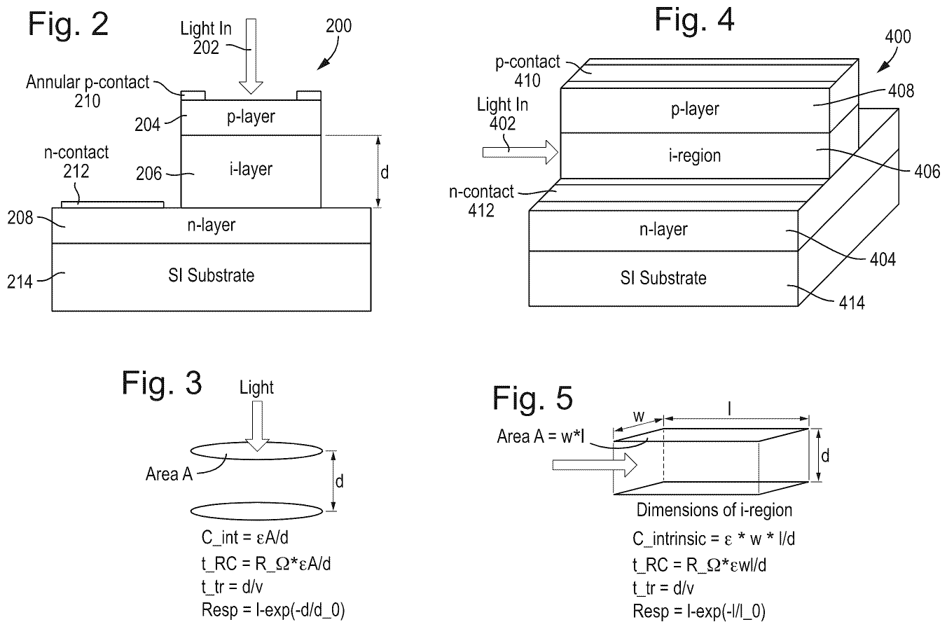

FIG. 2 is a simplified schematic diagram of a surface receiving vertical PIN PD with a top facet window, and normal incidence light in 200. A vertical PIN PD 202 typically has a circular cross-section comprising a p-layer 204, and i-layer 206 comprising absorption material, and an n-layer 208, with an annular top contact 210, in this case to the p-layer, and a bottom contact 212 to the n-layer. The PIN PD 200 is grown on a semi-insulating substrate 214 as described below. FIG. 3 explains how the device parameters are related in the FIG. 2 example. For example, responsivity Resp can be increased by increasing the thickness d of the i-layer comprising the absorption material, but increasing the thickness d increases the transit time of a carrier (electrons or holes) t_tr=d/v. In order to boost the responsivity, one might compensate for unabsorbed photons by using amplification, either optical pre-amplification, or post-amplification in the TIA electronics. It is noted that these approaches may introduce noise.

The equations that define the different parameters for the FIG. 2 arrangement are as follows:

$${C}_{int} = eA / d$$

$${t}_{RC} = {R}_{Ω} * eA / d$$

$$t\_tr = d / v$$

$$Resp = 1 - exp ( - d / {d}_{0} )$$

where Cᵢₙₜ is the intrinsic capacitance, A is the area of the i-region, d is thickness of the i-region, Resp (also referred to elsewhere as QE) is responsivity, R_{Ω} is resistance, e is the permittivity, v is the velocity of the carrier, t_{RC} is the RC limited time constant and d₀ is a material-dependent “absorption length” related to Beer's Law absorption. In the propagation direction, the optical field intensity reduces from any initial level by a factor of e (which stands for the base of a natural logarithm).

FIG. 4 is a simplified schematic diagram of an edge receiving waveguide device such as a PD 400 with a lateral facet window formed on a substrate for light in 402. The waveguide is a rectangular ridge waveguide of length l and width w comprising an n-layer 404, i-region 406 comprising absorption material and a p-layer 408; in this example the p-contact 410 is on top, and the n-contact 412 is on the bottom. The i-region has a thickness d. The PIN PD 400 is grown on a semi-insulating substrate 414 as described below. FIG. 5 explains how the device parameters are related in the FIG. 4 example. In this configuration, the responsivity Resp of the waveguide PD is dependent on the length l of the waveguide and is increased by increasing the length of the waveguide. The transit time depends on the thickness d of the i-region, and can be reduced by reducing the thickness d. Thus, the responsivity Resp is independent of transit time. Effectively this provides for increased absorption of received photons to manage optical coupling.

The equations that define the different parameters are as follows:

$${C}_{int} == e * w * l / d$$

$${t}_{RC} = {R}_{Ω} * ew l / d$$

$$t\_tr = d / v$$

$$Resp = 1 - exp ( - l / {l}_{0} )$$

where the area A is width*length=w*l of the i-region, d is thickness of the i-region, l₀ is a material-dependent “absorption length” related to Beer's Law absorption. It is noted that for surface illuminated the value d₀ because the depletion depth d is in the propagation direction as opposed to l₀ in the case of lateral propagation, thus explaining the differences in the formulae above. For a WG, depletion is orthogonal to propagation.

The devices are shown as PIN devices. In other words, comprising a p-layer, an intrinsic region and an n-layer. In many examples theses are shown with the p-layer on top and the n-payer on the bottom. This can be reversed, so generally, there is a first conductivity-type-layer and a second conductivity-type-layer separated by an intrinsic layer or region. Where the first layer is n-type the second will be p-type and vice versa. In alternative terminology, the i-region may be referred to as the absorption region or core of the waveguide, and first conductivity-type layer and the second conductivity-type layer may be referred to as the upper and lower cladding layers, i.e. the absorption region is sandwiched between a p-cladding layer and an n-cladding layer. It is noted for the avoidance of doubt that a layer referred to in the singular may in fact include multiple layers and vice versa. Some figures showing a singular layer are in fact multiple layers and a single layer is used for ease of understanding. The layer or layers making up any structure in part or in total may comprise other numbers of layers and different materials than those stated. All the layers are examples of shapes, sizes, numbers, materials and associated parameters that can all be varied from the examples shown. All examples are just that, an example, and not intended to be in anyway limiting, beyond, what is defined in the claims.

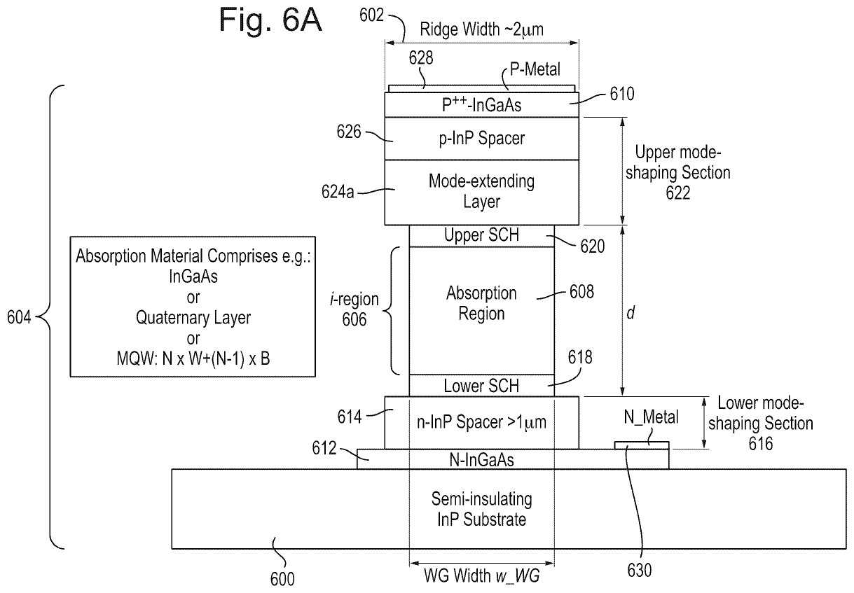

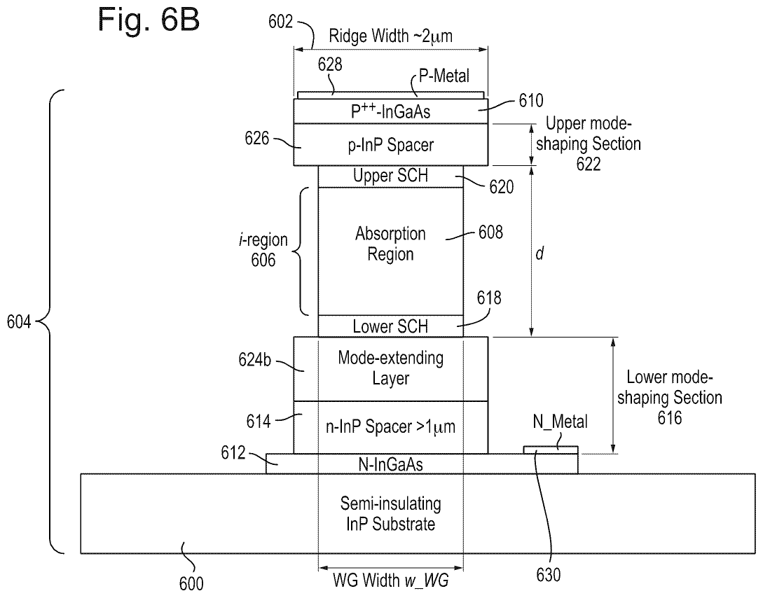

In the example waveguide device, such as a PD of an embodiment shown schematically in FIG. 6a and FIG. 6b, the substrate comprises semi-insulating (SI) InP, e.g. SI Fe doped InP 600. The waveguide is a ridge waveguide structure 602, wherein the ridge width is ˜2 μm. The ridge waveguide structure comprises an epitaxial layer stack 604 wherein the i-region 606 comprising absorption material or region 608 which is sandwiched between a p-contact layer 610 and p-cladding (also referred to herein as a mode shaping section 622) and an n-cladding (also referred to herein as a mode shaping section 616) and n-contact layer 612. The n-layers of the PD comprise the n-contact layer 612 of N—InGaAs and an n-InP spacer layer 614 of at least 1 μm thickness, which acts as a lower (second) mode-shaping section 616.

Typically, the thickness of the i-region is selected to provide a carrier transit time limit, e.g. a thickness in the order of ˜200 nm to 400 nm provides a transit time that is sufficiently fast for 448 Gb/s (and beyond) operations. It is noted that holes and electrons each travel at different velocities and the transit time may comprise an average based on the carrier velocity of holes and electrons. The average may be varied in a number of ways and may form parameters which can be balanced in the determination of the design requirements of the waveguide device. The thicknesses of the p-cladding and n-cladding in known devices are typically in the order of ≤1 μm. However, in the present invention these p-cladding and n-cladding layers are thicker than a typical cladding layers, and are structured, as will be explained below, to provide a mode-extension and/or a mode-shaping function.

The i-region 606 may comprise: an optional first separate confinement heterostructure (lower SCH) 618, the absorption region 608 comprising absorption material, and an optional second separate confinement heterostructure (upper SCH) 620. An upper (first) mode-shaping section 622 comprises a p-type mode-extending layer 624a or 624b, a p-InP spacer layer 626 and a p-contact layer comprising p⁺⁺-InGaAs 610. A P-metal contact 628 is provided on top of the ridge on the p⁺⁺-InGaAs layer. An N-metal contact 630 is provided on the N—InGaAs layer at the bottom. The device structure may be encapsulated with layer of dielectric, e.g. 0.5 μm silicon nitride in an example. The absorption region of the i-region may comprise an absorption material, such as for example, InGaAs, a quaternary absorption material, or a Multi-Quantum Well (MQW) structure, for example QCSE structure. The choice for the absorption material may be dependent on the intended use of the device and the required speed of operation.

For the purposes of this application and as described in greater detail throughout the application providing mode-shaping sections is used herein to describe features which provide optical confinement of one or more modes of an optical signal propagating through the absorption region 608 to maximize or at least provide more efficient capture of light in the WG PIN. It is noted that illustrated examples of the WG PIN show two mode-shaping sections, one of which includes a mode-extending structure. In examples only one mode-shaping regions may be possible, although there may be some degradation relative to other examples where there are two mode-shaping structures. The two mode-shaping regions (where there are two) may be similar or different. For example, the mode-extending structure may be found in one or both mode-shaping structures. As described elsewhere the mode-extending structures, if there are two may be the same of different.

One consideration for the device is to optimize the capacitance of the device. There are only certain things that can be controlled to influence this. In broad terms the device capacitance is given by:

$${C}_{device} = {C}_{int} + {C}_{pad}$$

There is not much to change other than Cᵢₙₜ, which is given above for two different types of device. This is true where l is the EAM device length and neglecting fringe capacitance, which is usually small compared with the main intrinsic capacitance and leads to the determination that the 3 dB R_{ΩC} limited bandwidth is given by;

$${f}_{3 dB} = 1 / ( 2 π {R}_{Ω Cdevice} )$$

This parameter f_{3 dB} relates to the cutoff frequency of the device and is an important metric in electronics as it indicates the frequency beyond which the response drops below one half of its response at DC (0 Hz).

In FIG. 6a the mode-extending layer 624a is shown as a p-type mode-extending layer located above the absorption region. In FIG. 6b the mode-extending layer 624b is shown as a n-type mode-extending layer located below the absorption region. Irrespective of the location the mode-extending layer provides a function of improving the efficiency of the optical coupling. Light into a device may comprise multiple modes. For example, a first order optical mode may have mode shape that has a Gaussian intensity profile, e.g. a circular or elliptical mode-shape including a central high intensity peak which diminishes radially, as is well known. Higher order modes have other mode shapes or patterns which may comprise multiple intensity peaks. Particularly in high-speed, low profile (size) devices ensuring as much light as possible, including multiple optical modes, is received and captured in the device is an ongoing challenge. The ability to maximize the amount of light whist preserving other operational parameters is important. The intensity (I) is given by the following formula:

$$I = {\sum }_{n = 0}^{∞} ( {I}_{n} exp ( - {Γ}_{n} {γ}_{abs} l )$$

### For Non-Bound Modes

Γₙ≈0

The max QE then becomes.

$$QE = \frac{{\sum }_{n = 0}^{∞} ( {I}_{n} exp ( - {Γ}_{n} {γ}_{abs , n} I )}{{\sum }_{n = 0}^{∞} {I}_{n}}$$

Where n is the mode and the variables are as stated below.

In developing their devices, the Applicant has determined that there are many parameters that may be balanced and optimized to achieve the performance required for PDs for use at 448 Gb/s in examples. One of these is the use of the mode-extending layer 624a/624b which is provided and located to optimize the light received in the main or any ancillary modes of light in from the fiber. As mentioned above the central peak of the primary mode (also known as the first order mode or fundamental mode) may be accompanied by other light from higher order modes. By including the mode-extending layer 624a/624b the amount of light captured from the primary mode and higher order modes can be increased whist not compromising others of the operating parameters which are required for high-speed operation. Other parameters may also be varied alone or in combination with use of the mode-extending layer 624a/624b as will now be described.

In order to maximize the responsivity (light captured) and ensure other parameters are not adversely impacted by this primary objective a number of different parameters can be adjusted to provide optimal operation of a PIN PD or equivalent for high-speed application. For a single mode, the variables which may influence the performance and design of the design can be summed up by the following equation:

$${( {f}_{3 dB} )}^{- 2} = [ {( \frac{2 π {R}_{Ω} ϵ {w}_{WG} l}{d} )}^{2} + {( \frac{d}{0.443 * {v}_{avg}} )}^{2} ]$$

Where f_{3 dB} refers to cutoff frequency of the device (i.e. where the device ceases to operate at an optimal performance); w_{WG} refer to width of the waveguide; QE is the responsivity of the photodiode (and provides the proportion or percentage of light absorbed compared to. light incident on the device); R_{Ω} is the ohmic resistance of the device; v_{avg} is the average velocity of the carriers; Γ is the mode overlap; γ_{abs} is the absorption coefficient (μm−1). For a single mode this can be used to calculate the responsivity and the length of the i-region as follows:

$$QE = 1 - exp ( - Γ {γ}_{abs} l )$$

$$∴ l = - \frac{ln ( 1 - QE )}{Γ {γ}_{abs}}$$

This can be similarly denoted to the nth mode as follows:

$${QE}_{n} = 1 - exp ( - {Γ}_{n} {γ}_{abs , n} l )$$

Where QEₙ is the responsivity or quantum efficiency of the device of modes n; and Γₙ is the mode overlap for the nth mode. As a result, the ideal length of the i-region can be determined of each mode and then optimized for all relevant modes that may be captured.

From the above equations it is clear that there are many variables that could influence the performance of the device. These include the variables in the above equations, the materials and any doping or shaping thereof as well as the shape and size of each layer that leads to interactions which further influence the performance of the device. No one variable is likely to lead to optimal performance, instead there are many degrees of freedom or parameters based on individual ones of the variable and it is by varying the degrees of freedom that an optimal device design can be arrived at for a specific application or device specification.

For the purposes of this application the variables or parameters are sometimes referred to as degrees of freedom, as some of them may be intrinsic as a result of the combinations of dimensions, materials, doping and the like and can be achieved through different so-called combinations of variable or parameters. For example, the length and doping of the intrinsic layer may be linked, and thus changing one intrinsically causes a change in the requirements for the other. So, balancing the two together may require the management of one or two degrees of freedom depending on the relationship between the variable or parameters. In another example the balance between the area and thickness of the i-region and the intrinsic capacitance are linked, optimizing one may be detrimental to the other. Having a thicker i-region increases the mode size of this region. At the same time the carrier transit time and capacitance are increased, which may be non-optimal. It is clear that the balance between the two relates to two degrees of freedom which are to be balanced (optionally along with others) to design a device having strong mode confinement and coupling whilst not increasing the transit time to unacceptable levels. It is noted that this may further be related to the number of other variable or parameters as described elsewhere.

For the avoidance of doubt degrees of freedom for the design of a high-speed device having optimal performance, include, but are not limited to, at least the following parameters (in no particular order):
The variables defined in the equations;
The nature of the device layers including their compositions, materials, doping and the like;
The nature, size and materials of the absorption region;
The mode-shaping structure or structures;
The mode-extending layer including the nature, size, position and materials thereof;
Mode confinement structures used to confine the light into certain layers of structures, for example cladding, spacers and the like;
The presence and absence of SCH layers;
The level of doping in any region of interest (for example, in the mode-extension structures and the mode-confinement structures);
The refractive indices of each layer, for example, of the mode-extension structures and the mode-confinement structures relative to the i-region;
The epitaxial growth process, for example MBE. MOCVD, or any other process;
The manufacturing process, for example photolithography, deposition equipment/technique, etching equipment/technique, or any other process;
The fall-off of voltage and electric field profile over the length of the intrinsic region;
The width of absorption region relative to the width of the waveguide;
The transit time of the carriers (holes and/or electrons as the case may be);
A thickness d of the i-region determines the carrier transit time, and is related to a transit time limit of the i-region;
Grading of certain layers of interest to provide smoothing of changes in one or more variable;
Whether MQWs are used and then the numbers of wells and barriers and the ratio of wells to barriers;
Undercutting of the absorption region or i-region for reducing the width of the i-region relative to the width of the ridge of the waveguide, e.g. to reduce capacitance;
Balancing the absorption length of the i-region with the RC value thereof, in the case of a surface receiving PD and a WG photodiode;
Variable doping of layers for grading and balancing;
The ability to accommodate a single mode and multiple modes as required and as available based on the “mode-capacity” of the i-region; and
The variation in the transit time of holes and electrons.

By careful selection and control of the degrees of freedom the Applicant has been able to design a high speed WG PIN which can outperform all currently available alternatives in the market. A plurality of degrees of freedom are determined, which are combined to give rise to an optimal device structure. One or more of the plurality of degrees of freedom are selected based on the required performance criteria or parameters of interest. Different situations and uses may provoke a different one or ones of the plurality of degrees of freedom being selected. The improvement margins are of the order of the order of a factor of two for a figure of merit based on quantum efficiency (QE) and bandwidth. The term balancing used herein with reference to the degrees of freedom or parameters, is not intended to relate to equality but instead the balance of one degree of freedom being arranged to be optimal without being unduly detrimental to any other degree of freedom. Selecting one or more of the plurality of degrees of freedom and then balancing the selected ones is not a trivial operation. Instead, it takes inventive merit to combine and balance the degrees of freedom to both work and more importantly work in an effective and efficient manner.

As with all designs for devices, optimal performance comes from judicious control of the device parameters and variables (or the one or more degrees of freedom for the design). At least some of the determinations that a particular device parameter; variable or degree of freedom for the design is important comes from “testing” the design and then varying the parameter, variable or degree of freedom. One area where this has proved to be of interest is the management of multiple modes.

In a typical situation where a WG PIN diode is used as an optical receiver, the WG PD receives a high speed modulated optical signal from a transmission source, e.g. via an optical fiber or on chip waveguide. The modulated optical signal may excite a single mode or multiple optical modes of the WG PIN PD. Light is captured by the WG PD and converted to photocurrent, which is output as high speed modulated electrical signal to a transimpedance amplifier (TIA) in an example.

For optimal performance of a WG PIN it is good for the quantum efficiency (QE) of the device to be as close to 1 as possible. A QE of 1 or responsivity close to 100% means that all light received in converted to electrical energy. In practice is desirable that the QE or responsivity is close to 1, so that a high proportion or incident light is captured in the WG PIN diode and the overall intensity of light in the waveguide is a maximized. A high quantum efficiency is one of the conditions necessary for efficiency and high-speed performance. The QE may be enhanced by designing the WG PIN to support more than one bound optical mode. Accordingly, one of the considerations used in designing and building the optimal WG PIN device is to consider the absorption of light for more than one WG PIN PD mode.

Additionally, it is important to consider the mode overlap or coupling between each of the bound modes supported by the WG PIN PD and the incoming fiber mode. This may be a design parameter or a result based on other design parameters. Either way, capturing more light is advantageous.

In the context of the present application, high-speed relates to operating devices at speeds required in optical communications that are destined for use in, for example, high-speed modulation schemes such as 224 Gb/s, 336 Gb/s and 448 Gb/s PAM4 modulation applications and the like. Further the devices may be used for applications using wavelength division multiplexing (WDM) comprising optical signals of multiple wavelengths which are multiplexed onto a single optical fiber, for example, using multiple wavelengths in the O-band, L-band and C-band wavelength ranges. WDM networks include e.g. high-speed optical data interconnects for data centers, which may be short range optical interconnects within a data center, or longer-range optical interconnects between data centers, 5G network optical communications and other similar forms of transmission and reception technique. For example, 10Gigabit-capable PON may be referred to as 10G-PON or XG-PON. Recommendation ITU-T G.987 is a family of documents that define this access network standard. Simultaneous upstream and downstream transmission over the same fiber is made possible through wavelength division multiplexing (WDM). This technology allows one PON wavelength transmission for upstream and another for downstream. For example, 10G-PON uses 1577 nm for downstream and 1270 nm for upstream.

In the FIG. 6a and FIG. 6b examples and in accordance with one or more degrees of freedom or parameters of the design, the width of absorption region of the waveguide w_WG, is narrower than the ridge width, to reduce the device area of the i-region and therefore reduce the intrinsic device capacitance per unit length. For example, the mode-extending layer may comprise a quaternary material having a refractive index which is greater than the refractive index of the InP spacer layers, and less than the refractive index of the absorption material of the i-region. For example, if the InP spacer layers have a refractive index of 3.21, and the absorption material of the i-region has a refractive index of 3.3 to 3.4, the mode-extending layer may comprise a quaternary material having a refractive index in a range of 3.28 to 3.30. The upper and lower mode-shaping regions provide for more efficient optical coupling between the fundamental mode of the WG PIN PD and the fiber mode owing to the increased optical spot size of the former. A semi-insulating substrate reduces parasitics for the waveguide PD itself, and for the contact pads. The semi-insulating substrate also allows for independent control of the N-contact and P-contact for operation with a differential TIA.

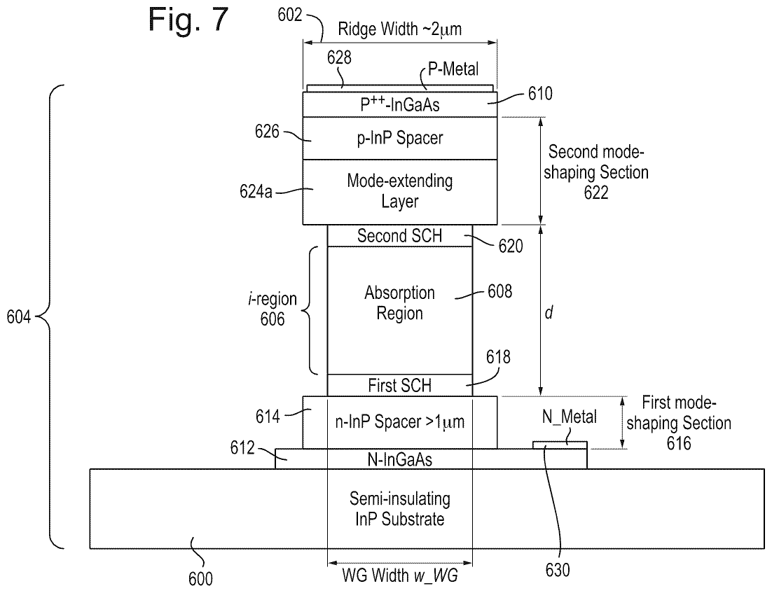

For example, for the waveguide device such as the PD of the embodiment illustrated schematically in FIG. 7 and in accordance with one or more degrees of freedom or parameters of the design, the i-region comprises InGaAs which has strong absorption and very fast response.

InGaAs as an absorption material covers a large wavelength range e.g. O-band, C-band and L-band.

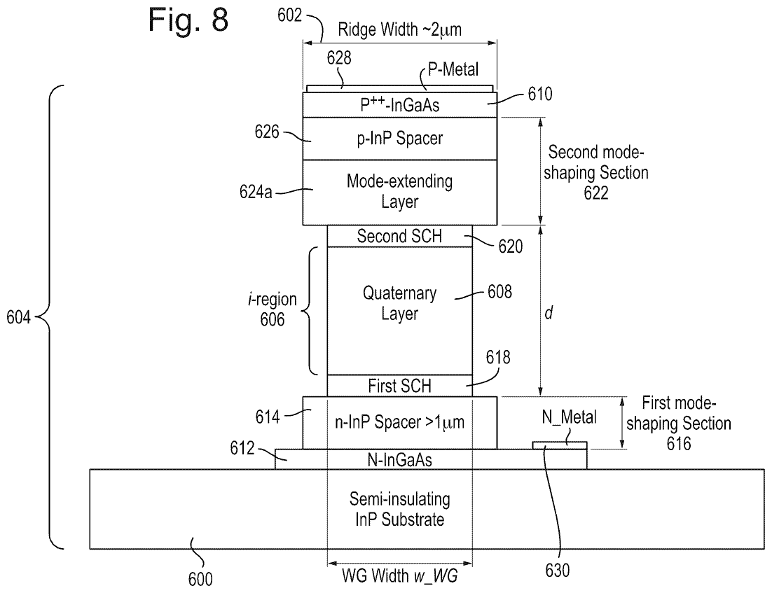

For example, for the waveguide device such as the PD of the embodiment illustrated schematically in FIG. 8 and in accordance with one or more degrees of freedom or parameters of the design, the i-region comprises an absorption material, which may be a quaternary absorption material within the InGaAlAsP quintenary materials system, which is lattice matched to InP, e.g. InGaAsAl or InGaAsP.

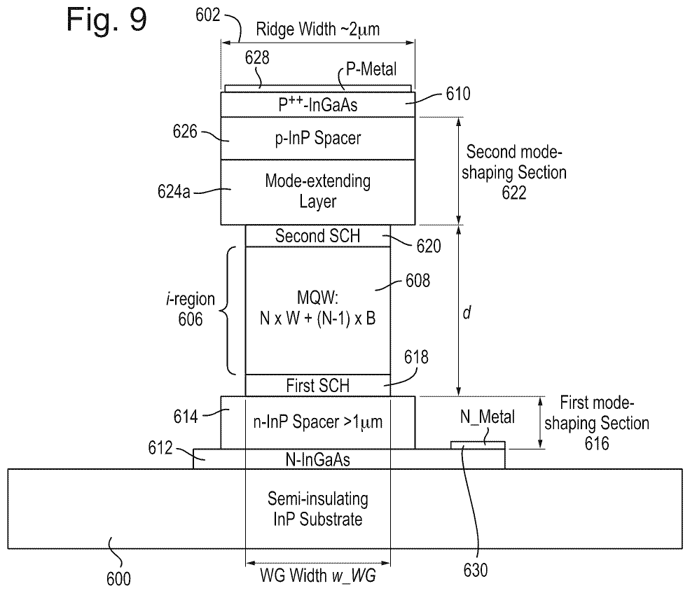

For example, for the waveguide device such as the PD of the embodiment illustrated schematically in FIG. 9 and in accordance with one or more degrees of freedom or parameters of the design, the i-region comprises a MQW structure of N wells (W) and N−1 barrier layers (B), which is denoted by “N×W+(N−1)×B”. That is, the waveguide PD is structured as a QCSE EAM. This option has a restricted operational wavelength range and requires temperature control but may be preferred for some applications. The MQW layers can be fabricated using MOCVD, MBE or other growth techniques. The strength of the excitonic binding energy for QCSE can be affected by the choice and specific implementation parameters of the growth technique. Control of the dopant for the n-layers and the p-layers provides for adjusting the capacitance. Typical MOCVD growths use Zn as the p-type dopant. MBE can provide Be as the p-type dopant, which is an advantage because Be is less mobile than Zn. This allows the junction with the i-region to be more abrupt, so that the p-i-n structure is defined to be more manufacturable.

As illustrated schematically in FIG. 9, the width of the i-region of the EAM waveguide is narrower than the upper width of the ridge. For example, the i-region is undercut relative to the width of the ridge. Reducing the width of the active absorption region or the i-region reduces capacitance per unit length. Upper and lower mode-shaping sections extend the optical mode vertically, which allows for reducing the EAM waveguide width in the i-region to reduce capacitance per unit length. For example, the width of the ridge may be in the range from 2 μm to 3 μm, e.g. 2.3 μm to 2.5 μm, and the width of the i-region may be undercut by 0.25 μm to 0.5 μm each side. The width of the ridge waveguide may be tapered along its length, for example the width of the ridge may narrow along its length from the optical input to the back facet of the waveguide photodiode. To increase the f_3 dB bandwidth, it is desirable to reduce the width of the i-region to provide a lower intrinsic capacitance per unit length, e.g. ≤0.70 fF/μm. For example, for an EAM having a length of 50 μm, the device capacitance is <35 fF. The mode-shaping sections extend the optical mode vertically to reduce parasitic insertion loss, e.g. to improve optical coupling to the waveguide, and mode-shaping can also reduce metallization losses. The lower mode-shaping section is a spacer layer of n-InP having a thickness of at least 1 μm. The upper mode-shaping section may comprise a layer of quaternary material and a p-InP spacer layer. The quaternary material has a refractive index between the refractive index of InP and the effective refractive index of an i-region. For example, if the MQWs comprise an InGaAsAl MQW structure having an effective refractive index in a range of 3.3-3.4, e.g. 3.35, and the spacer layer of InP has a refractive index of e.g. 3.21, the quaternary layer of the upper mode-shaping section may comprise InGaAsP having a refractive index in the range 3.28 to 3.30. The thickness of the upper mode-extending layer is e.g. 0.8 μm.

An optical isolator may be required to block back reflection to the laser, but if most of the laser light is absorbed in the WG PD, an optical isolator may not be required.

The waveguide PDs can be fabricated with one or more of an on-chip resistor for load matching or design optimization, a capacitor, and an inductor.

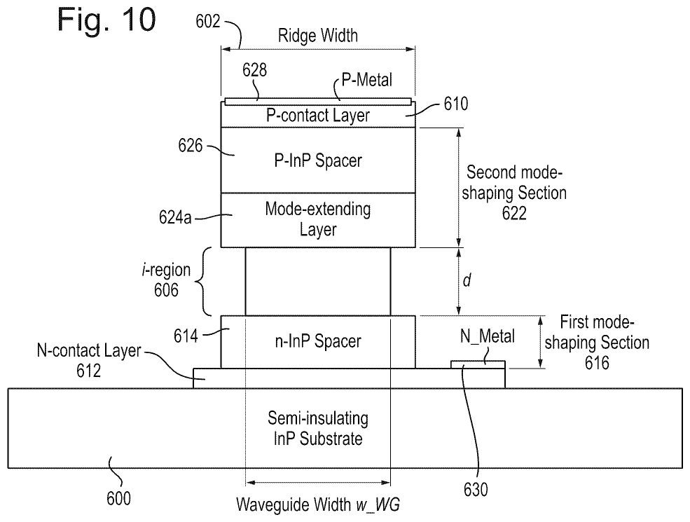

FIG. 10 to FIG. 13 each show alternatives to the previous example embodiments and it will be appreciated that there may be still more variations that are not shown in a specific figure. Like references refer to similar structures but these may comprise different materials than shown in the figures. This is particularly the case where the devices shown are n-up or p-up as the case may be. In FIGS. 10 to 13, the darker grey indicates for example a higher refractive index layers of the i-region, a lighter grey for example a lower refractive index InP spacer layer, and intermediate grey for example, the mode-extending layers which may have an intermediate refractive index. This is by way of example and to aid understanding but is not intended to be limiting to the nature of the refractive indexes in these figures or any others having similar coloring or shading.

FIG. 10 shows a simplified schematic cross-sectional view of a waveguide device such as the PD of an embodiment wherein the p-cladding and p-contact is on top and the n-cladding and n-contact is underneath the i-region, as described for the embodiment shown in FIG. 6a. The substrate comprises semi-insulating (SI) InP, e.g. SI Fe doped InP. The ridge waveguide structure comprises an epitaxial layer stack wherein the i-region comprising absorption material which is sandwiched between a p-contact layer and p-cladding and an n-cladding and n-contact layer. For example, the n-layers comprise a n-contact layer of N—InGaAs and an n-InP spacer layer, which acts as a lower mode-shaping section. The i-region comprises an absorption region comprising absorption material. An upper mode-shaping section that comprises a p-type mode-extending layer, a p-InP spacer layer and a p-contact layer comprising p⁺⁺-InGaAs. A P-metal contact is provided on top of the ridge on the p-contact layer. An N-metal contact is provided on the N—InGaAs layer at the bottom. The device structure is encapsulated with layer of dielectric.

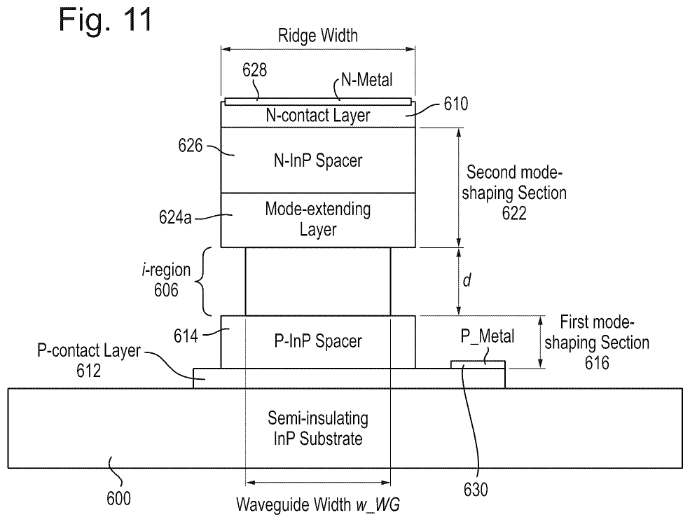

FIG. 11 shows a schematic cross-sectional view of a waveguide device such as the PD of an embodiment wherein the n-cladding and n-contact is on top and the p-cladding and p-contact is underneath the i-region. The substrate comprises semi-insulating (SI) InP, e.g. SI Fe doped InP. The ridge waveguide structure comprises an epitaxial layer stack wherein the i-region comprising absorption material which is sandwiched between an n-contact layer and n-cladding and an p-cladding and p-contact layer. For example, the p-layers comprise a p-contact layer of p-InGaAs and an p-InP spacer layer, which acts as a lower mode-shaping section. The i-region comprises an absorption region comprising absorption material. An upper mode-shaping section that comprises an n-type mode-extending layer, an n-InP spacer layer and an n-contact layer e.g. comprising n-InGaAs is provided. An n-metal contact is provided on top of the ridge on the n-contact layer. A p-metal contact is provided on the p-InGaAs layer at the bottom. The device structure may be encapsulated with layer of dielectric.

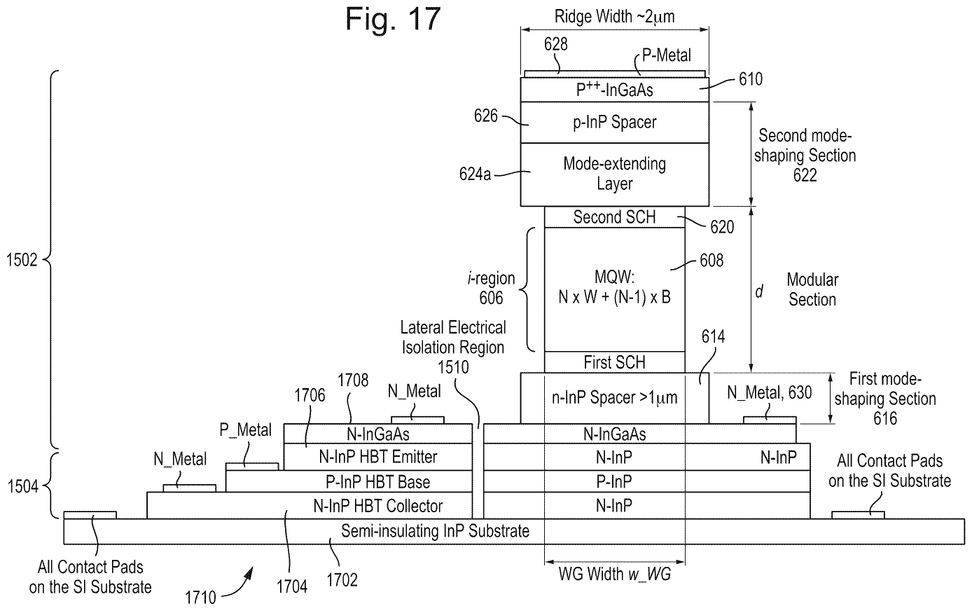

As described above, the absorption region of the i-region may comprise InGaAs, a quaternary absorption material, or a QCSE Multi-Quantum Well (MQW) structure. The i-region may include upper and lower SCH layers. In this embodiment, the width of absorption region of the waveguide w_WG, is narrower than the ridge width, to reduce the device area of the i-region and therefore reduce the intrinsic device capacitance per unit length. For example, the mode-extending layer may comprise a quaternary material having a refractive index which is greater than the refractive index of the InP spacer layers, and less than the refractive index of the absorption material of the i-region. The upper and lower mode-shaping regions provide for more efficient optical coupling with a larger optical spot size. A semi-insulating substrate reduces parasitics for the waveguide PD itself, and for the contact pads. The SI substrate also allows for independent control of the n-contact and p-contact for operation with a differential TIA. Optionally, electronics layers may be provided between the SI substrate and the photonics layers of the waveguide device such as the PD, e.g. as described with reference to FIG. 17.

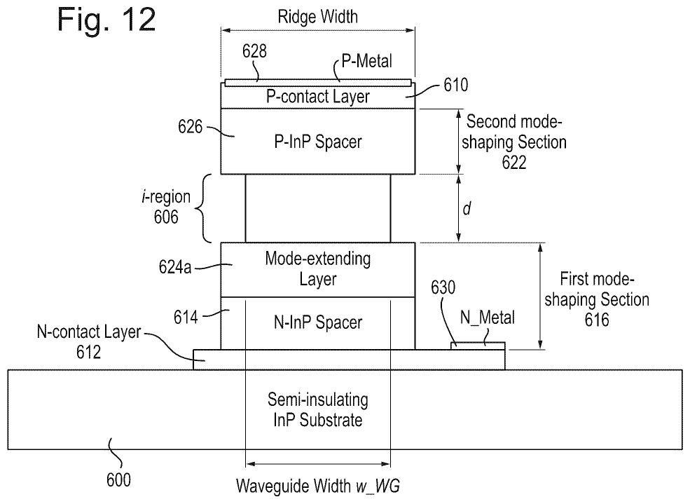

FIG. 12 is similar to FIG. 10 with the mode-extending layer provided underneath the i-region and omitted above.

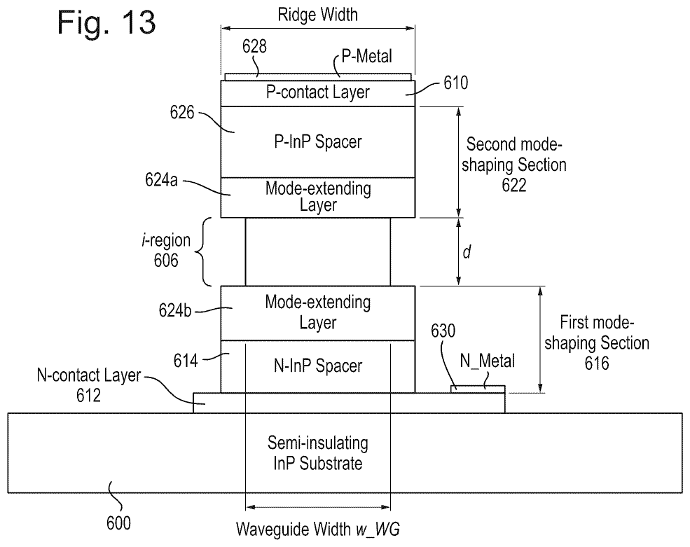

FIG. 13 shows a schematic cross-sectional view of a waveguide device or PD of an embodiment wherein a mode-extending layer is provided above and below the i-region. For example, each mode-extending layer may be a quaternary material having a refractive index intermediate the adjacent InP spacer layer and the i-region. In this example, the p-cladding layers are on top and the n-cladding layers are below the i-region. Alternatively, the n-cladding layers are on top, and the p-cladding layers are below the i-region. Elements of the waveguide structure shown in FIG. 13 are similar to those described for FIG. 10, with the addition of a mode-extending layer underneath the i-region, as well as a mode-extending layer above the i-region. Optionally, electronics layers may be provided between the SI substrate and the photonics layers of the waveguide PD, e.g. as described with reference to FIG. 17.

In FIG. 13 different thicknesses of upper and lower mode-extending sections are used to illustrate schematically that the structure need not be vertically symmetric above and below the i-region and each layer could be independently optimized or balanced. In some examples as one of the degrees of freedom or parameters mentioned above. In another embodiment the first and second (upper and lower) mode-extension layers may have vertical symmetry of the waveguide relative to centre of i-region. For example, a circularly symmetric first order optical input mode from a single mode fibre is centred on the i-region. Other optimized coupling of multiple modes of different shapes, i.e. more complex multimode coupling of different mode shapes in which each layer thickness may be separately optimized is also envisaged. Accordingly, FIG. 13 is just one example of a mode-extending layer being provided above and below the i-region. Similarly, there may be different layers proximate to the mode-extending layers as long as their function serves to provide a manner in which an extension of a mode or modes can be captured by the mode-extending layer.

As previously indicated the figures show non-limiting examples of combinations of layers and materials and many of these could be changeable depending on the design requirements of the device and the purpose thereof.

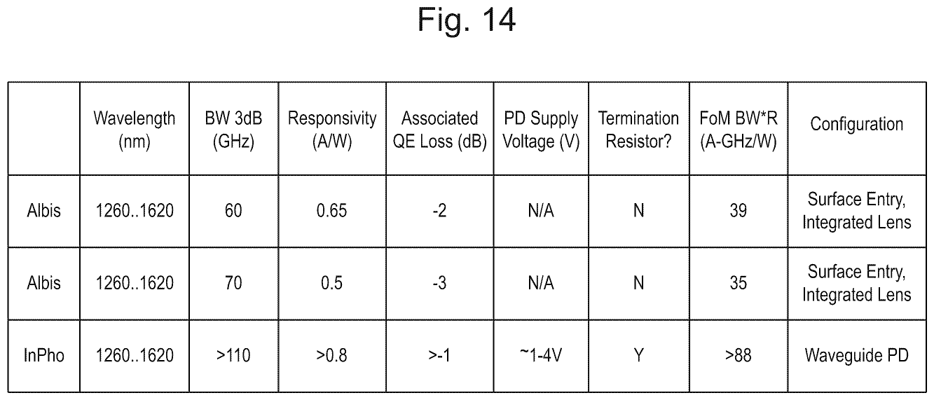

FIG. 14 shows some comparative data for two commercially available surface illuminated PD with integrated lens, and a waveguide device or PD of an example embodiment comprising a QCSE waveguide PD as illustrated schematically in FIG. 9.

In the waveguide PD of example embodiments described in detail above and in accordance with one or more degrees of freedom or parameters of the design, by way of example, the thickness (d or tᵢ) of the i-region is selected to limit the transit time, and the length of the waveguide and the absorption material is selected to provide a required Responsivity (Quantum Efficiency) over a required operational wavelength range. Even though the i-region is thin, the waveguide area is small from the perspective of εA/d, which provides a low capacitance. The performance is RC limited, not transit time limited. Fabricating the waveguide on a semi-insulating substrate also reduces device capacitance. For the i-region, InGaAs has good absorption and is very fast. Use of a quaternary absorption material is a trade-off of a bit speed but provides a more controllable spot size. For QCSE waveguides, fabrication of the MQW structure using MBE provides sharper, more abrupt quantum wells than fabrication by MOCVD. The intrinsic region is thin, so there is a constant E field across it.

To achieve increased responsivity (QE) and in accordance with one or more degrees of freedom of the design, a mirror or reflector, e.g. a metal coating, can be added to the back facet of the WG PD to allow for two-passes of absorbed light, i.e. to increase the effective absorption length of the i-region. An optical isolator may be required to block back reflection to the laser, but if most of the laser light is absorbed in the WG PD, an optical isolator may not be required.

The extrinsic capacitance, e.g. pad capacitance, can be reduced to a range of 10 fF-15 fF in practice with good growth and fabrication techniques. The intrinsic capacitance can be reduced through ridge design, e.g. reducing the width of the i-region. The intrinsic capacitance of the waveguide PD may be reduced by providing a ridge that is tapered from a first width at the optical input facet to a second width at the back facet, where the second width is narrower than the first width. Since most of the absorption occurs in the i-region closer to the optical input facet, reducing the width of the ridge, and the width of the i-region towards the back facet does not significantly reduce responsivity.

To obtain maximum overlap between optical mode and quantum wells within the MQW i-region and in accordance with one or more degrees of freedom of the design, the number of MQW is increased. Conventional EAMs typically use 8 MQW. A waveguide PD of an example embodiment listed in FIG. 9 comprises 13 MQWs. The number of MQW could be further increased, e.g. to ≥16 MQW and in examples as much as 24 where other factors are not negatively impacted by the higher number of wells. A larger number of MQW allows for higher optical mode overlap with the MQWs. The barrier to well thickness ratio is typically 1:1, and each layer is ˜10 nm thick, e.g. in a range from 9 nm to 11 nm. For example, reducing the barrier to well thickness ratio to <1:1, e.g. 6 nm: 10 nm, leads to a 1 dB improvement in quantum efficiency. Thus, the number of MQWs can be increased, together with lower barrier/well thickness ratio, until the transit time limit of the i-region is reached.

To provide accurate control and fidelity of E-field and in accordance with one or more degrees of freedom of the design, it is preferable to use MBE over MOCVD for fabrication, to provide more abrupt junctions. Use of a low physical mobility p-type dopant, e.g. Be rather than Zn, or C if possible, provides for a one-sided abrupt junction, and low-unintentionally doped intrinsic region. Diffusion of the n-type dopant, e.g. Si, is not usually an issue. Well defined junctions allow for a near-constant E-field across the intrinsic region, very little voltage drop outside the intrinsic region, and very little optical coupling outside the intrinsic region. Optical coupling outside the intrinsic region would lead to loss or, worse, diffusion tails.

For example and in accordance with one or more degrees of freedom or parameters of the design, the waveguide materials, and waveguide dimensions comprising the waveguide width, waveguide length and thickness of the i-region are selected to provide a high minimum responsivity or quantum efficiency, and low capacitance per unit length: e.g. quantum efficiency (QE) ≥80% over a required operational wavelength range, and a capacitance of ≤0.70 fF/μm of length; or a quantum efficiency (QE) ≥90% over a required operational wavelength range, and a capacitance of ≤0.70 fF/μm of length. The responsivity in A/W is wavelength dependent. For example, 80% QE at 1300 nm wavelength is 0.84 A/W, and 90% QE at 1300 nm wavelength is 0.9 A/W.

For coupling to outside world, the effective spot size of the edge-receiving optical facet can be increased by optimizing the waveguide structure: e.g. the epilayer structure processing and lateral ridge dimension, to enable optical coupling to a spot size of ˜2 μm, without resorting to a spot-size converter. Addition of a spot size converter adds significant length and optical loss. For example, upper and lower mode-shaping-sections are provided as illustrated schematically in FIG. 7 and in accordance with one or more degrees of freedom or parameters of the design. The thickness of the i-region is increased up to close to a transit time limit of the i-region. The upper and lower SCH can be used to fine tune the thickness of the i-region. The upper and lower SCH may be omitted for non-MQW i-regions comprising InGaAs or a quaternary absorption material, or the upper and lower SCH may be included for grading of the conduction band energy Ec or valence band energy Ev, or optical index profiling.

In waveguide PD structures described above, a thick layer of InP is used to separate the mode from the InGaAs of the HBT, to reduce undesired absorption. A mode-extending layer may be provided above the i-region as described above, and/or below the i-region. The mode-extending layer may have a refractive index greater than the refractive index of the InP spacer layers, and less than the refractive index of the i-region. The mode-extending layer is used to shape the mode so as to extend the mode either above or below the i-region for improved optical coupling, but judiciously so as to prevent unwanted absorption in the InGaAs and metal layers above, or the InGaAs layer below.

In the waveguide PD of example embodiments illustrated in the Figures, the p-contact and p-layers are on top, and the n-contact and n-layers are at the bottom of the waveguide structure. In alternative embodiments, the waveguide structure may be fabricated with the p-contact and p-layers at the bottom and the n-contact and n-layers at the top.

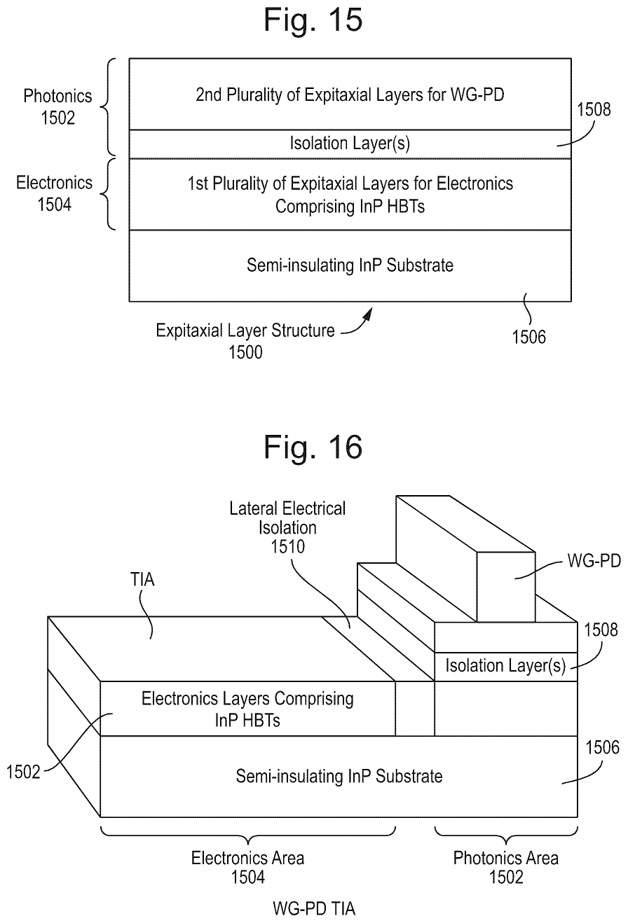

FIG. 15 shows a simplified epitaxial layer structure 1500 for fabrication of a monolithic electro-photonic circuit comprising photonics layers 1502 such as a waveguide photodiode and electronics layers 1504 such as a transimpedance amplifier (TIA). The epitaxial layer stack comprises a semi-insulating InP substrate 1506, a first plurality of semiconductor layers 1504 fabricated on the SI substrate and structured for fabrication of electronics comprising InP Heterojunction Bipolar Transistors (HBTs); an isolation layer 1508 comprising one or more layers providing electrical isolation and mode separation layer(s); and a second plurality of semiconductor layers 1502 structured for fabrication of the optical waveguide layer of the waveguide PD. The photonics area of the epitaxial layer stack is processed to define the waveguide structure of the waveguide PD, and expose the electronics layer in the electronics area as illustrated schematically in FIG. 16. An isolation trench 1510 provides lateral electrical isolation between the electronics for the HBTs, and the remaining layers of the first plurality of semiconductor layers left underlying the photonics. The isolation layer 1508 provide vertical separation of the photonics layers from underlying electronics layers.

A schematic cross-sectional view of a monolithic electro-photonic integrated circuit comprising a waveguide PD and a transimpedance amplifier (TIA) is shown in FIG. 17, based on an epitaxial layer structure as illustrated schematically in FIG. 15 and FIG. 16. The waveguide PD structure is the same as that illustrated schematically in FIG. 9 and in accordance with one or more degrees of freedom or parameters of the design wherein the i-region comprises a MQW absorption structure. It will be appreciated that FIG. 17 could have the i-region equivalent to that shown in any other example, including but not limited to FIGS. 6A, 6B, 7, 8 and 9. Also the combinations of mode-shaping and mode-extending layers as shown and as described above could also be incorporated into an example similar to FIG. 17. The illustration in FIG. 17 is merely one example of an appropriate structure and all combinations or alternatives described elsewhere could be incorporated therein. Like reference refer to similar layers as in the examples above and the materials stated are not intended to be limiting and could be according to any examples described herein.

The monolithic electro-photonic integrated circuit 1700 comprises the SI InP substrate 600 on which is formed the first plurality of semiconductor layers comprising a stack of: an N—InP layer, a P—InP layer and an N—InP, layer and an N—InGaAs layer. In the electronics area 1504 of the monolithic electro-photonic integrated circuit: for each InP HBT, these layers form, respectively, an N—InP HBT collector 1702, a P-HBT base 1704, an N—InP HBT emitter 1706, and an N—InGaAs contact 1708. One HBT 1710 is shown by way of example, One or more metallization layers are provided to form HBT contacts and interconnections of the HBTs. N-metal contacts are provided to each of the N—InP collector and the N—InGaAs contact layer. A P-metal contact is provided to the P—InP base. In the photonics area 1502 of monolithic electro-photonic integrated circuit, the first plurality of semiconductor layers remain under the photonics, and are laterally electrically isolated 1510 from those layers in the electronics area by the lateral electrical isolation region. One of the metallization layers provides electrical interconnect between the waveguide PD and the input of the TIA.

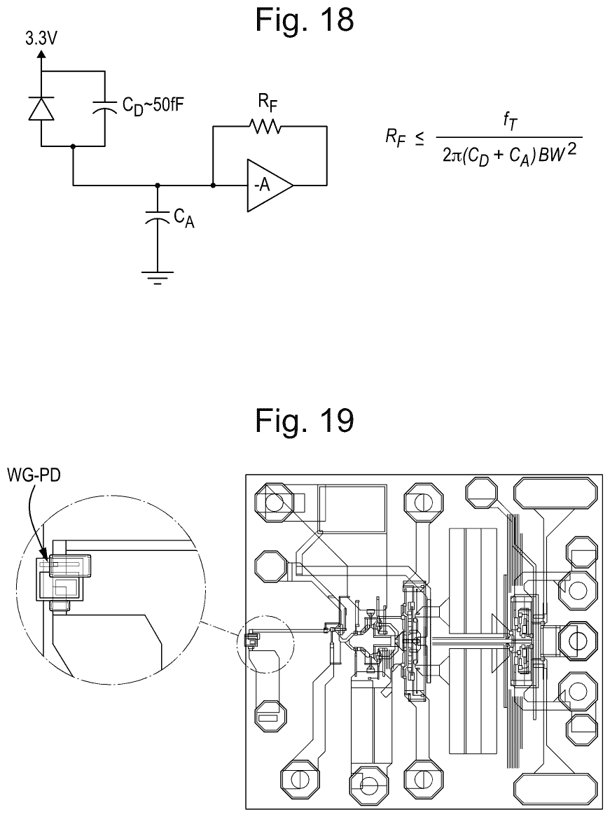

FIG. 18 shows a simplified equivalent circuit schematic for the PD and TIA to illustrate key parameters for design of the monolithically integrated PD-TIA design of the example embodiment, in an aspect of the invention. In addition, the figure includes an equation under which values of components may be determined in an example.

FIG. 19 shows an example circuit layout for a monolithically integrated waveguide PD and TIA, in an aspect of the invention.

Monolithic integration of the waveguide PD and TIA provides for electrical interconnect between the waveguide PD and the TIA which is very short, e.g. ≤20 μm. Direct on-chip interconnection of the PD and the TIA, using lithographically defined conductive traces, instead of wire-bonding or flip-chip bonding of discrete components, eliminates pad capacitances and interconnect parasitics (interconnect inductance/resistance/capacitance).

The signal and signal-to-noise response of the monolithically integrated waveguide PD and TIA is limited by the TIA electronics and noise created in the first stage of the TIA. Providing a PD with a lower input capacitance reduces the noise. The waveguide PD in accordance with one or more degrees of freedom or parameters of the design can have a relatively short waveguide, e.g. ≤40 μm. Waveguides of length 25 μm, 20 μm and 15 μm have been demonstrated to provide sufficient responsivity. A short waveguide has less capacitance, which is good for bandwidth which is limited by capacitance.

Reference herein to HBTs is understood to include Single Heterostructure Bipolar Transistors (SHBTs) and Double Heterostructure Bipolar Transistors (DHBTs) and other types of HBTs.

The device structures disclosed herein may be fabricated with III-V semiconductor materials, e.g. group III-V semiconductor materials, such as an Indium Phosphide (InP)-based material system comprising binary, ternary, quaternary and other compositions of In, Ga, As, P, Al and Sb. For example, the SI substrate is Fe-doped InP, and the HBTs and EAM waveguides are fabricated from an InP-based material system, comprising selected binary, ternary and quaternary and other compositions of In, Ga, As, P, Al, and Sb. In some embodiments, the epilayer structure is compatible with a single epitaxial growth process. In other embodiments, a multiple growth process is used.

For example, the MQW layers can be fabricated using MOCVD, MBE or other growth techniques. The strength of the excitonic binding energy for QCSE can be affected by the choice and specific implementation parameters of the growth technique. Control of the dopant for the n-layers and the p-layers provides for adjusting the capacitance. Typical MOCVD growths use Zn as the p-type dopant. MBE can provide Beryllium (Be) as the p-type dopant, which is an advantage because Be is less mobile than Zn. This allows the junction with the i-region to be more abrupt, so that the p-i-n structure is defined to be more manufacturable in accordance with one or more degrees of freedom or parameters of the design.

To provide accurate control and fidelity of E-field, it is preferable to use MBE over MOCVD for fabrication, to provide more abrupt junctions. Use of a low physical mobility p-type dopant, e.g. Be rather than Zn, or C if possible, provides for a one-sided abrupt junction, and low-unintentionally doped intrinsic region. Diffusion of the n-type dopant, e.g. Si, is not usually an issue. Well defined junctions allow for a near-constant E-field across the intrinsic region, very little voltage drop outside the intrinsic region, and very little optical coupling outside the intrinsic region. Optical coupling outside the intrinsic region would lead to loss or, worse, diffusion tails.

For coupling to outside world, the effective spot size of the edge-receiving optical facet can be increased by optimizing the waveguide structure: e.g. the epilayer structure; processing and lateral ridge dimension, to enable optical coupling to a spot size of ˜2 μm, without resorting to a spot-size converter. Addition of a spot size converter adds significant length and optical loss. For example, upper and lower mode-shaping sections are provided as illustrated schematically in FIGS. 6A and 6B. The thickness of the i-region is increased up to, a value related to the transit time limit of the i-region. When the thickness of the i-region is below a limit related to the transit time limit the bandwidth is RC limited. The upper and lower SCH can be used to fine tune the thickness of the i-region in accordance with one or more degrees of freedom of the design.

It is noted that the waveguide device as described herein is generally shown as a waveguide photodiode (PD) that would be used in a receiver. It is also intended that a similar configuration can be used to produce device combinations suitable for an EAM and a suitable driver (with or without a laser source or sources) as used in a transmission-related device. This is described in more details on our co-pending application having common priority data herewith and incorporated herein by reference.

Although example embodiments have been described and illustrated in detail, it is to be clearly understood that the same is by way of illustration and example only and not to be taken by way of limitation, the scope of the present invention being limited only by the appended claims.

1. A waveguide (WG)-device comprising a p-type material, an i-type material and an n-type materials (a PIN waveguide), the waveguide device comprising:
a semi-insulating (SI) indium phosphide (InP) substrate;
an epitaxial layer stack formed on the SI:InP substrate structured to form the PIN waveguide, the epitaxial layer stack comprising:
an n-layer structure and a p-layer structure;
an i-region located between the n-layer structure and the p-layer structure;
wherein the n-layer structure and the p-layer structure are configured to optically confine one or more modes of an optical signal configured to propagate through the i-region;
at least one of the n-layer structure and the p-layer structure comprising a mode-extending layer; and
the i-region comprising an optical material defining an operational wavelength range and a selected thickness (d);
wherein the selected thickness of the i-region is to balance;
a capacitance of the i-region and a transit time ty of carriers in the i-r ion, the carriers comprising at least one of holes and electrons, where tₜᵣ=d/v, and v is a velocity of the carrier; and
the selected thickness of the i-region in combination with the mode-extending layer is to accommodate absorption of the one or more modes of the optical signal in the i-region.

2. The waveguide device of claim 1, wherein the waveguide device is a waveguide-photodiode, and the i-region comprises an absorptive optical material.

3. (canceled)

4. The waveguide device of claim 1, wherein the n-layer structure includes at least one of an n-cladding layer and an n-contact layer and the p-layer structure includes at least one of a p-cladding layer and a p-contact layer.

5. (canceled)

6. The waveguide device of claim 1, fabricated with group III-V semiconductor materials, including an Indium Phosphide (InP)-based material system comprising binary, ternary, quaternary and other compositions of In, Ga, As, P, Al and Sb, and wherein the mode-extending layer comprises a quaternary material.

7. The waveguide device of claim 1, wherein the mode-extending layer comprises a layer of the n-type structure having a refractive index higher than a refractive index of another layer of the n-layer structure.

8. The waveguide device of claim 1, wherein the mode-extending layer comprises a layer in the p-layer structure having a refractive index higher than a refractive index of another layer of the p-layer structure.

9. The waveguide device of claim 1, wherein the week mode-extending layer comprises:
a layer in the n-layer structure having a refractive index higher than a refractive index of another layer of the n-layer structure, and
a layer type layer in the p-layer structure having a refractive index higher than a refractive index of another layer of the p-layer structure.

10. (canceled)

11. The waveguide device of claim 1, wherein a required performance of the waveguide device is achieved by further balancing at least one of:
parameters of a compositions, size, materials or doping of the epitaxial layer stack;
inclusion of one or more mode-shaping structures;
inclusion of one or more separate confinement heterostructure (SCH) layers;
defining a refractive index of each layer of the epitaxial layer stack
selecting processing from MBE. MOCVD, or any other process;
balancing fall-off of voltage and/or electric field profile over a length of the i-region;
balancing a width of the i-region relative to the width of the waveguide device;
grading of one or more layers of the epitaxial layer stack;
inclusion of multi-quantum well MQW material and where used balancing a number of wells and barriers and a thickness ratio of wells to barriers;
providing an undercut to the i-region for reducing the width of the i-region relative to the width of the ridge of the waveguide, to reduce capacitance;
balancing an absorption length of the i-region with a RC value thereof;
balancing a waveguide width, waveguide length and the selected thickness of the i-region to provide a quantum efficiency (QE) of between ≥80% and (QE) ≥90% over a required operational wavelength range;
balancing a waveguide width, waveguide length and the selected thickness of the i-region to provide a capacitance of ≤0.70 fF/μm of length; and
wherein the waveguide is a ridge waveguide having a ridge width and a ridge length, and the i-region has a width which is less that the ridge width.

12. The waveguide device of claim 1, wherein the material of the i-region comprises InGaAs.

13. The waveguide device of claim 1, wherein the optical material of the i-region comprises a quaternary absorption material selected within the InGaAlAsP quintenary system.

14. The waveguide device of claim 1, wherein the material of the i-region comprises a Quantum Confined Stark Effect (QCSE) multi-quantum well (MQW) structure, comprising N wells and N−1 barriers.

15. The waveguide device of claim 14, wherein N is between ≥8 and =24

16. The waveguide-photodiode of claim 14, wherein the well thickness, the barrier thickness and N are selected to provide the selected thickness d of the i-region which is close to a transit time limit of the i-region.

17. The waveguide device of claim 14, wherein a ratio of the barrier thickness to well thickness comprises one of:
a) 1:1;
b) <1:1; and
c) 6:10.

18. The waveguide device of claim 1, wherein a width of the i-region is tapered, having a first width at an optical input and narrowing to a second width at a back facet of the waveguide device.

19. An optical device comprising a waveguide device according to claim 1 and further comprising a monolithically integrated first plurality of semiconductor layers of the epitaxial layer stack forming at least one electronic device.

20. The optical device of claim 19, wherein the waveguide device is a waveguide-photodiode or an electro-absorption modulator (EAM).

21. The optical device of claim 19, wherein the at least one electronic device comprises a transimpedance amplifier (TIA) or an electro-absorption modulator (EAM) driver.

22. The optical device of claim 19, wherein the optical device is a receiver, the waveguide device is a waveguide-photodiode and the at least one electronic device comprises a transimpedance amplifier (TIA).

23. The optical device of claim 19, wherein the optical device is a transmitter, the waveguide device is an electro-absorption modulator (EAM) and the at least one electronic device comprises an electro-absorption modulator (EAM) driver.

24. The optical device of claim 22, wherein the TIA comprises InP heterojunction bipolar transistors (HBTs) formed by the first plurality of semiconductor layers of the epitaxial layer stack formed on the SI InP substrate and the waveguide device is formed by a second plurality of semiconductor layers of the epitaxial layer stack overlying the first plurality of semiconductor layers.

25. The optical device of claim 22, wherein device parameters comprise a capacitance of the waveguide-photodiode (PD), and a capacitance C_{TIA} of the TIA, wherein: device parameters comprising said C_{TIA} and a capacitance C_{PD} of the photodiode, dimensions of the i-region of the waveguide-photodiode comprising an area of the waveguide-photodiode and the selected thickness d of the i-region, and a transimpedance feedback resistance R_{F} of the TIA are selected to provide an integrated waveguide-photodiode-TIA meeting device specifications comprising a specified sensitivity and responsivity for the operational wavelength range.

26. The optical device of claim 22, wherein the waveguide-photodiode and the transimpedance amplifier (TIA) are formed monolithically on the semi-insulating (SI) indium phosphide (InP).

27. (canceled)

28. The optical device of claim 19, in an optical system comprises two or more optical devices.

29. The optical device of claim 28, comprising one or more first optical devices, the or each operating as a transmitter and one or more second optical devices the or each acting as a receiver.

30. A method of manufacturing a waveguide device comprising a p type material, an i-type material and an n-type material (a PIN waveguide) as defined in claim 1, comprising:
forming an epitaxial layer stack on a semi-insulating (SI) indium phosphide (InP) substrate and the epitaxial layer stack structured to form the PIN waveguide, comprising:
an n-layer structure and a p-layer structure; and
an i-region of the i-type material located between the n-layer structure and the p-layer structure;
wherein the n-layer structure and the p-layer structure are configured to optical confine one or more modes of an optical signal propagate through the i-region; and
at least one of: the n-layer structure comprising a n-type mode-extending layer having a refractive index greater than a refractive index of another layer of the n-layer structure; and the p-layer structure having a p-type mode extending layer having a refractive index greater than a refractive index of another layer of the p-layer structure, and
the i-region comprising an optical material defining an operational wavelength range and a selected thickness (d);
wherein the selected thickness of the i-region is processed to balance;
a capacitance of the i-region and a transit time tₜᵣ of carriers in the i-region, the carriers comprising at least one of holes and electrons, where tₜᵣ=d/v, and v is a velocity of the carrier; and
the selected thickness of the i-region in combination with the mode-extending layer is configured to accommodate absorption of the one or more modes of the optical signal in the i-region.

31. (canceled)

32. The waveguide device of claim 1, wherein the selected thickness of the i-region provides a transit time limit for operation at a modulation bandwidth of ≥50 GHz.

33. A waveguide (WG)-device comprising a p-type material, an i-type material and an n-type materials (a PIN waveguide), the waveguide device being a ridge waveguide having a ridge width and comprising:
a semi-insulating (SI) indium phosphide (InP) substrate;
an epitaxial layer stack formed on the SI:InP substrate structured to form the PIN waveguide, the epitaxial layer stack comprising:
an n-layer structure and a p-layer structure;
an i-region located between the n-layer structure and the p-layer structure;
wherein the n-layer structure and the p-layer structure are configured to optical confine one or more modes of an optical signal to propagate through the i-region; and
the i-region comprising an optical material defining an operational wavelength range and having a width less than the ridge width.

34. The method of claim 30, further comprising processing the epitaxial stack to define a ridge of the PIN waveguide having a length, a thickness and a width, and wherein a width of the i-region is processed to be to be less than the ridge width.

35. A method of manufacturing a waveguide device comprising a p type material, an i-type material and an n-type material (a PIN waveguide) as defined in claim 33 and comprising:
forming an epitaxial layer stack on a semi-insulating (SI) indium phosphide (InP) substrate and the epitaxial layer stack structured to form the ridge waveguide having the ridge width, comprising:
an n-layer structure and a p-layer structure;
an i-region located between the n-layer structure and the p-layer structure;
wherein the n-layer structure and the p-layer structure are configured to optical confine one or more modes of an optical signal to propagate through the i-region; and
the i-region comprising an optical material defining an operational wavelength range and processed to form a width less than the ridge width.
